(19) United States
(12) Patent Application Publication
(10) Pub. No.: US 2011/0065282 A1
(43) Pub. Date: Mar. 17, 2011

(54) APPARATUS AND METHODS TO FORM A PATTERNED COATING ON AN OLED SUBSTRATE

(75) Inventors: Min Yan, Niskayuna, NY (US); Larry Gene Turner, Niskayuna, NY (US); Ahmet Gun Erlat, Niskayuna, NY (US); William Francis Monaghan, Troy, NY (US); David J. Smith, Niskayuna, NY (US)

(73) Assignee: GENERAL ELECTRIC COMPANY, Schenectady, NY (US)

(21) Appl. No.: 12/557,767

(22) Filed: Sep. 11, 2009

(51) Int. Cl. H01L 51/56; C23C 16/455; C23C 14/34; C23C 14/35

(52) U.S. Cl. 438/758; 118/726; 118/723 FI; 204/298.11; 257/E51.026

(57) ABSTRACT

An apparatus for applying a patterned coating to an OLED substrate in a continuous roll-to-roll vapor based deposition process is provided comprising a vapor deposition source, a processing drum, a drive roller, and a shadow mask wherein the shadow mask comprises a mask line feature that selectively prevents deposition of the coating onto the substrate. Also presented is a method for applying the coating.

### BACKGROUND

In an OLED device, electrons and holes injected from the cathode and anode, respectively, combine in an emissive layer producing singlet and triplet excitons that can decay radiatively producing light or non-radiatively producing heat. For most organic molecules, light emission from the triplet state is a spin-forbidden process that does not compete well with non-radiative modes of decay, so triplet excitons are not very emissive. Transition metal complexes, by virtue of spin-orbit coupling, can radiatively decay with an efficiency that competes with non-radiative pathways. When these complexes are incorporated into OLED devices it is possible to achieve nearly 100% internal quantum efficiency since both singlet and triplet excitons produced in the device can emit light.

In case of roll-to-roll (R2R) fabrication of organic light emitting diode (OLED) devices on flexible plastic film, the organic layers, such as hole injection layer (HIL), hole transport layer (HTL), emission material layer (EML), and electron transport layer (ETL), which collectively may be referred to as OLED layers, can be coated continuously by printing methods, such as slot die or gravure coating, and patterned continuously by solvent assist wipe method (US20050129977 A1) at high throughput with low cost. But the inorganic electron injection layer (EIL) and metal cathode (patterned Aluminum) layer can only be put down by evaporation through shadow mask in vacuum in a stop-and-go batch process.

The batch shadow mask evaporation process is a stop-and-go process wherein the substrate with the OLED layer (OLED substrate) is first move into position, stopped from moving, and a flat metal shadow mask is pushed against the surface of the OLED substrate. This is followed by evaporation of EIL material (such as NaF, KF, etc) and metal (such as aluminum, calcium, barium, etc) onto substrate through a shadow mask. This stop-and-go operation contributes to a low throughput process, which limits the speed of the OLED line.

### BRIEF DESCRIPTION

This invention is aimed at directly creating pre-determined coating lanes in vapor-based deposition system using selective masking onto continuously moving OLED substrate.

In one aspect, the present invention relates to an apparatus for applying a patterned coating to an OLED substrate in a roll-to-roll vapor based deposition process comprising a vapor deposition source capable of depositing a coating on to the OLED substrate, a processing drum capable of positioning the OLED substrate for coating by the vapor deposition source, a drive roller capable of transferring the OLED substrate from a feed roll to a take up roll and controlling tension of the OLED substrate on the processing drum, and a shadow mask in close proximity to the processing drum wherein the curvature of the shadow mask matches the curvature of the processing drum. The shadow mask comprises one or more mask line features parallel to the moving direction of the OLED substrate wherein the mask line features selectively prevent deposition of the coating on the OLED substrate forming lanes between coating bands, and one or more beam features perpendicular to the moving direction of the OLED substrate wherein the beam features provide mechanical support to the line features.

In another aspect, the present invention relates to a method of applying a patterned coating to an OLED substrate in a roll-to-roll vapor based deposition process. The process involves providing an OLED substrate, providing a drive roller to allow continuous movement of the OLED substrate from a feed roll to a take-up roll, providing a processing drum and a shadow mask positioned between the feed roll and the take-up roll, providing a vapor deposition source positioned below the shadow mask, positioning the OLED substrate on the feed roll and take up roll such that the OLED substrate is wrapped around the processing drum and is in close approximation to the shadow mask, transporting the OLED substrate from the feed roll to the take-up roll using the drive roller, and depositing a coating on to the OLED substrate from the vapor deposition The shadow mask is in close proximity to and matches the curvature of the processing drum and comprises one or more mask line features parallel to the moving direction of the drive rollers wherein the mask line features selectively prevent deposition of the coating on the OLED substrate to form lanes between coating bands, and one or more beam features perpendicular to the moving direction of the OLED substrate wherein the beam features provide mechanical support to the line features.

### DRAWINGS

These and other features, aspects, and advantages of the present invention will become better understood when the following detailed description is read with reference to the accompanying drawings in which like characters represent like parts throughout the drawings.

FIG. 1 is a representative apparatus for applying a patterned coating to an OLED substrate.

FIG. 2 is a representative shadow mask showing line and beam feature

FIG. 3 shows positioning of the shadow mask relative to the processing drum.

FIG. 4a shows a large area OLED lighting device and alignment of the cathode coating bands.

FIG. 4b shows the layered OLED structure with offset distances between non-coated areas in each layer.

FIG. 5 is a representative processing drum with a recess area.

FIG. 6 shows multiple views of a two-drum system with a single deposition source.

FIG. 7 is a flow diagram of a method of applying a patterned coating to an OLED substrate.

### DETAILED DESCRIPTION

An optoelectronic device includes, in the simplest case, an anode layer and a corresponding cathode layer with an electroluminescent layer disposed between the anode and the cathode. When a voltage bias is applied across the electrodes, electrons are injected by the cathode into the electroluminescent layer, while electrons are removed from (or “holes” are “injected” into) the electroluminescent layer by the anode. For an organic light emitting device (OLED), light emission occurs as holes combine with electrons within the electroluminescent layer to form singlet or triplet excitons, light emission occurring as singlet and/or triplet excitons decay to their ground states via radiative decay. For a photovoltaic (PV) device, light absorption results in an electric current flow.

Other components, which may be present in an optoelectronic device in addition to the anode, cathode and light emitting material, include a hole injection layer, an electron injection layer, and an electron transport layer. The electron transport layer need not be in direct contact with the cathode, and frequently the electron transport layer also serves as a hole-blocking layer to prevent holes migrating toward the cathode. Additional components, which may be present in an organic light-emitting device, include hole transporting layers, hole transporting emission (emitting) layers and electron transporting emission (emitting) layers.

The organic electroluminescent layer, i.e. the emissive layer, is a layer within an organic light emitting device which, when in operation, contains a significant concentration of both electrons and holes and provides sites for exciton formation and light emission. A hole injection layer is a layer in contact with the anode which promotes the injection of holes from the anode into the interior layers of the OLED; and an electron injection layer is a layer in contact with the cathode that promotes the injection of electrons from the cathode into the OLED; an electron transport layer is a layer which facilitates conduction of electrons from the cathode and/or the electron injection layer to a charge recombination site. During operation of an organic light emitting device comprising an electron transport layer, the majority of charge carriers (i.e. holes and electrons) present in the electron transport layer are electrons and light emission can occur through recombination of holes and electrons present in the emissive layer. A hole transporting layer is a layer which when the OLED is in operation facilitates conduction of holes from the anode and/or the hole injection layer to charge recombination sites and which need not be in direct contact with the anode. A hole transporting emission layer is a layer in which when the OLED is in operation facilitates the conduction of holes to charge recombination sites, and in which the majority of charge carriers are holes, and in which emission occurs not only through recombination with residual electrons, but also through the transfer of energy from a charge recombination zone elsewhere in the device. An electron transporting emission layer is a layer in which when the OLED is in operation facilitates the conduction of electrons to charge recombination sites, and in which the majority of charge carriers are electrons, and in which emission occurs not only through recombination with residual holes, but also through the transfer of energy from a charge recombination zone elsewhere in the device.

The cathode may be comprised of a generally electrically conductive layer. The general electrical conductors include, but are not limited to metals, which can inject negative charge carriers (electrons) into the inner layer(s) of the OLED. Metal oxides such as ITO may also be used. Metals suitable for use as the cathode include K, Li, Na, Cs, Mg, Ca, Sr, Ba, Al, Ag, Au, In, Sn, Zn, Zr, Sc, Y, elements of the lanthanide series, alloys thereof, and mixtures thereof. Suitable alloy materials for use as the cathode layer include Ag—Mg, Al—Li, In—Mg, Al—Ca, and Al—Au alloys. Layered non-alloy structures may also be employed in the cathode, such as a thin layer of a metal such as calcium, or a metal fluoride, such as LiF, covered by a thicker layer of a metal, such as aluminum or silver.

In certain embodiments, the OLED substrate may be a continuous polymer sheet comprised of at least one of poly (3,4-ethylenedioxythiophene) (PEDOT), poly (3,4-propylenedioxythiophene) (PProDOT), polystyrenesulfonate (PSS), polyvinylcarbazole (PVK), combinations thereof, and the like.

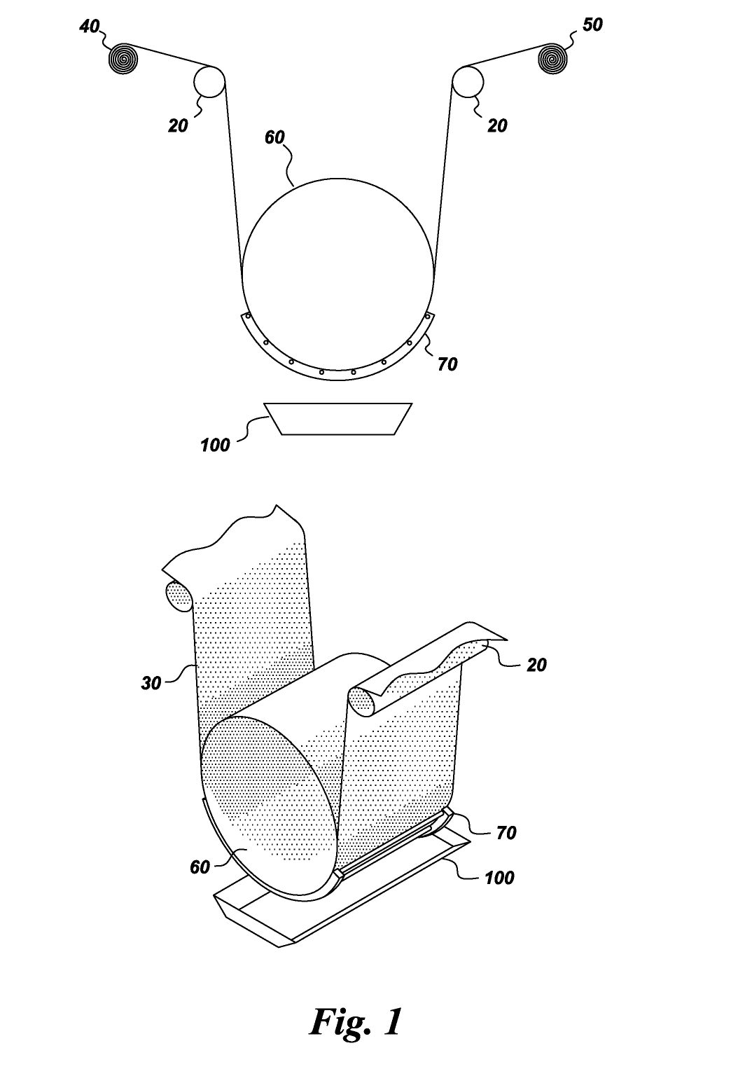

In one embodiment, an apparatus is provided for applying a patterned coating to an OLED substrate in a continuous roll-to-roll vapor based deposition process The apparatus is generally shown in FIG. 1 and is comprised of at least one drive roller (20) that may be used to allow continuous movement of an OLED substrate (30) from a feed roll (40) to a take up roll (50). Positioned between the feed roll and the take up roll is a processing drum (60) wherein the OLED substrate is in contact with the peripheral portion of the processing drum. The processing drum is configured to rotate during the coating process. The drive roller may be used to apply a fixed amount of tension to the moving substrate to keep it in uniform contact with the processing drum and to prevent contact with the shadow mask (70) during operation. The processing drum may also comprise a temperature regulator (not shown) to control the temperature of the substrate.

A shadow mask (70) is in close proximity to and matches the curvature of the processing drum. The shadow mask is comprised of mask line features which are positioned parallel to the moving direction of the OLED substrate. The mask line features selectively prevent deposition of the coating on the OLED substrate to form lanes between coating bands.

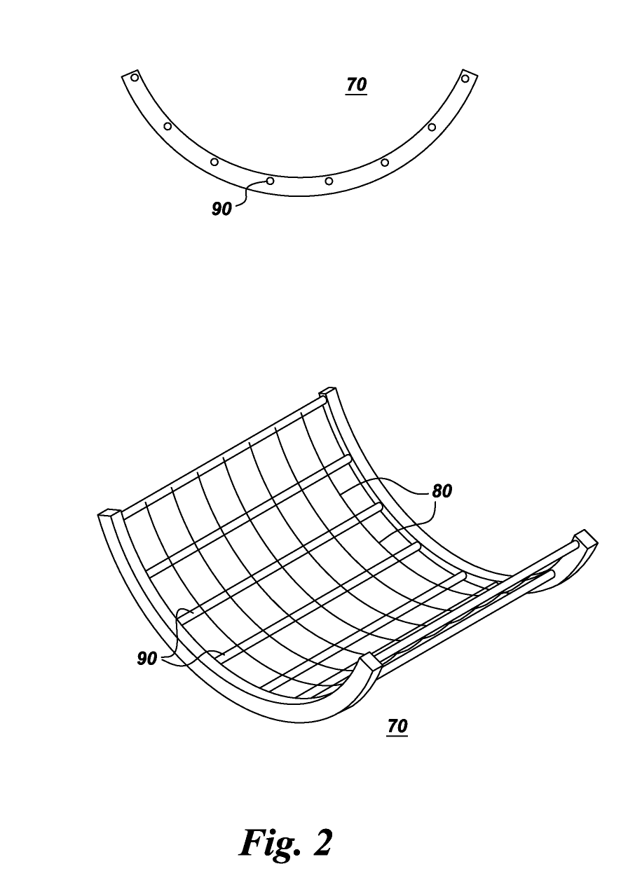

As shown in FIG. 2 the mask line features (80) block deposition medium from coating the area between “line” features and substrate, forming non-coated area commonly referred to as a “street” between coating bands. The width of the mask line features determines the width of the street between coating bands. In one embodiment, the mask line features may have capability to adjust its position in cross substrate moving direction, which can provide flexibility in changing width of coating band. The shadow mask is also comprised of one or more beam features (90), which are positioned perpendicular to the moving direction of the OLED substrate and provide mechanical support to the line features and may prevent the mask line features from deformation related to thermal or mechanical stress. The beam feature may also be comprised of an active temperature regulator. In certain embodiments the temperature regulator may be comprised of a flowing cooling agent in center of the beam feature wherein the beam feature is formed from a hollow metal tube.

The shadow mask is in close approximation to the processing drum to create a uniform gap through which the OLED substrate passes during the deposition process. During the deposition process, the distance between the shadow mask and substrate should be sufficiently small to prevent a shadow effect. A shadow effect is defined as a situation when deposition medium diffuses into the area between mask line feature and substrate, and coats the “street” area that shouldn't be coated. Similarly, the gap between shadow mask and substrate must be sufficiently large enough so that the shadow mask will not physically scratch substrate. In certain embodiments, the width of the gap between the shadow mask and the processing drum ranges from 1 micron to 2000 micron and preferably from 1 micron to 200 microns.

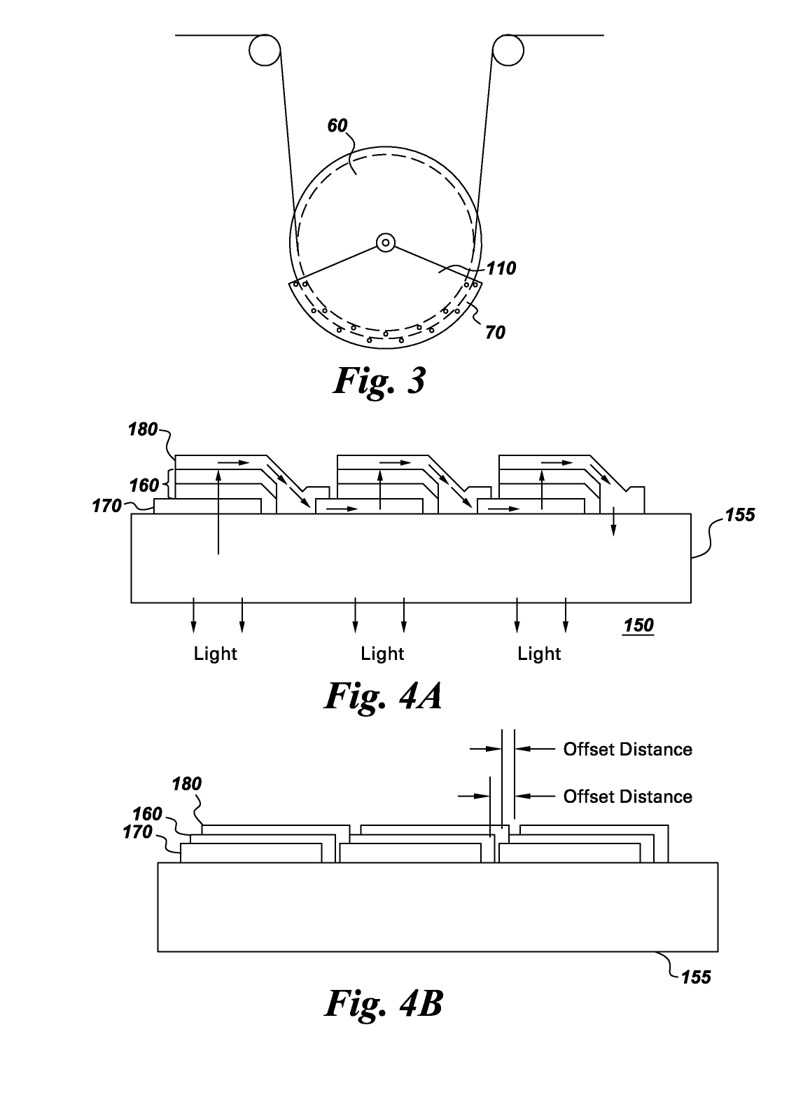

The shadow mask may be comprised of a low thermal expansion alloy, such as INVAR®(ArcelorMittal) to prevent mask from deforming under elevated temperature. In certain embodiments, as shown in FIG. 3, the shadow mask may also have solid metal plates (110) positioned on either or both sides to provide mechanical support and attach it to axle of central processing drum or to deposition's chamber.

Referring again to FIG. 1, a vapor deposition source (100) is positioned below the shadow mask. The deposition source can be evaporation sources such as thermal evaporation source or e-beam evaporation source, ion beam assisted evaporation sources, plasma assisted evaporation sources, sputtering sources such DC sputtering, DC magnetron sputtering, AC sputtering, pulsed DC sputtering, and RF sputtering.

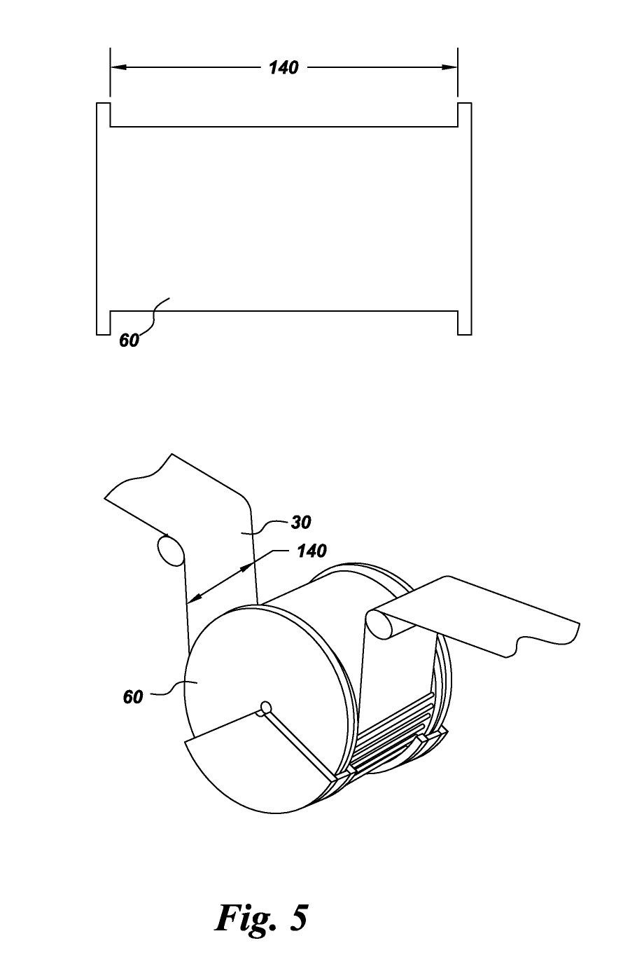

In certain embodiments, it may be necessary to have alignment between coating bands and features that have already be formed on a substrate (155). For example, as shown in FIG. 4a, in case of a large area OLED lighting device (150), it may be desirable to form monolithic series connect between neighboring pixels (depicted as pathway arrows in FIG. 4a) which requires aligning cathode coating bands (180) to underlying previously formed and patterned organic thin films (160) and transparent conductors (170). The “street” areas in transparent conductor (170) and in cathode coating (180) are used to separate neighboring pixels. The “street” areas in organic thin films (160) are used to allow cathode coating (180) be in electrical contact with transparent conductor (170) to form monolithic series connection. The emitting area (pixel) is defined by the area that the cathode coating (180), overlaps with the transparent conductor (170).

As shown in FIG. 4b, to maximize emitting areas in OLED lighting devices, it may be desirable to minimize “street” width and minimize the offset distance between “street” in cathode coating (180), in organic thin films (160), and in transparent conductor (170). Reduced “street” width and offset distance in each layer will require precise control of the position of the “street” in each layer. Thus it will require precisely positioning the substrate in the cross web moving direction during cathode deposition.

In certain embodiments controlling the cross web-moving position of the substrate may be achieved by using a processing drum comprising a recessed area as shown in FIG. 5 The recess area of the processing drum (60) has the same width (140) as that of substrate (30). In an alternative embodiment, the cross web position of the substrate may be controlled by using a web steering unit, such as a Micro 1000 web guide control system (accuWeb Inc.). The steering system may operate by actively monitoring the position of the substrate on the processing drum and adjusting its position.

It may be desirable to form a coating with a varied deposition rate. In certain embodiments a thin layer of metal may be deposited initially on the OLED substrate using a slow deposition rate on the order of angstroms/minute in order to avoid damage to the OLED substrate. When a continuous thin (around 100 angstroms) metal film has formed, which has the capability of protecting organic thin films; the deposition rate may be increased to a higher rate (nanometers per second) for increased productivity.

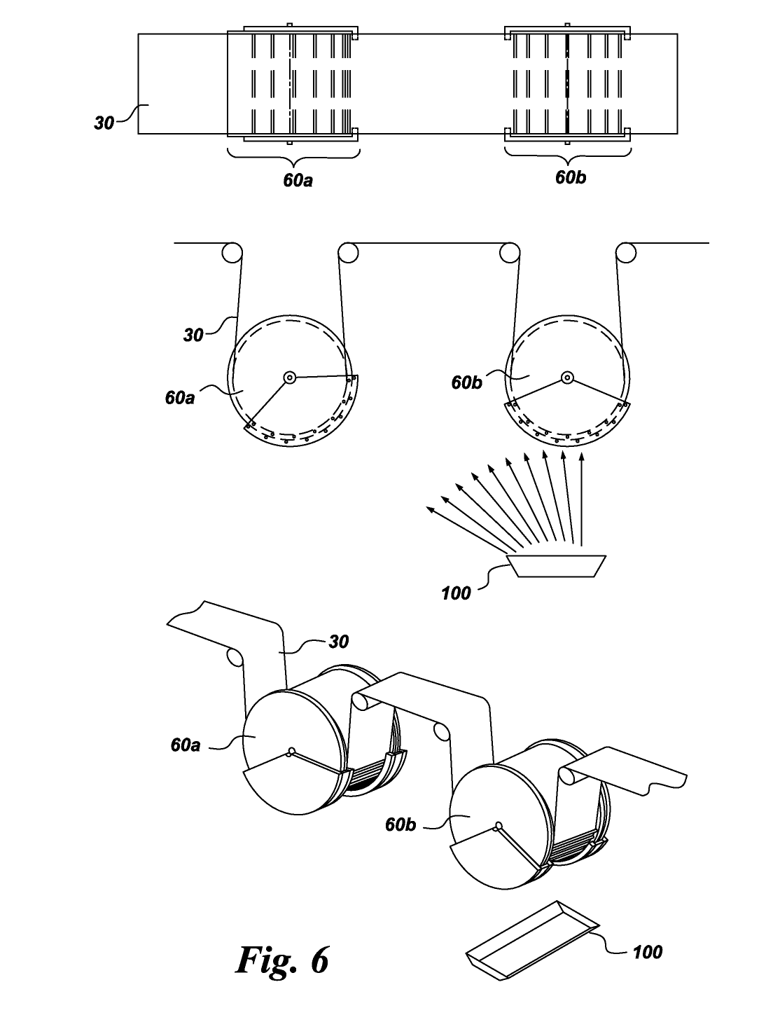

As shown in FIG. 6, a two-drum system with a single deposition source may be used to vary the coating deposition rate. Since deposition rate decreases as a square function of distance between substrate and source, the first drum (60a) will receive a coating with a lower deposition rate compared to the second drum (60b).

In still yet another embodiment, a shutter device may be added to the deposition source, to temporarily stop deposition onto substrate and form a break of coating in the substrate moving direction.

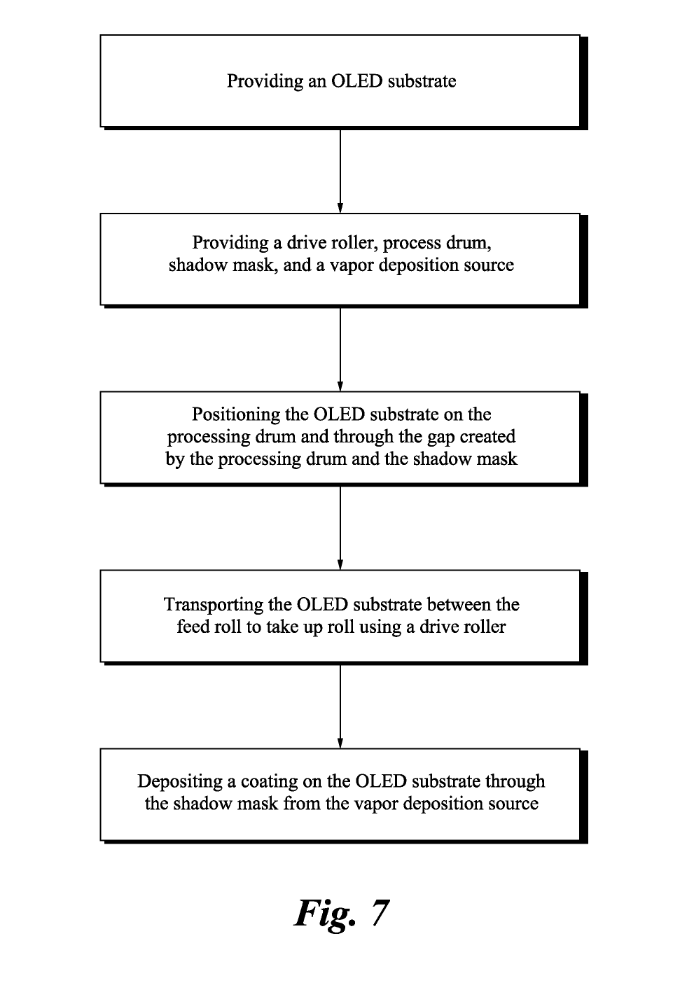

In other embodiments, as shown in FIG. 7, a method of applying a patterned coating to an OLED substrate in a roll-to-roll vapor based deposition process is provided. The method comprises the steps of providing an OLED substrate, providing a drive roller to allow continuous movement of the OLED substrate from a feed roll to a take-up roll, providing a processing drum and a shadow mask, positioned between the feed roll and the take-up roll, wherein the shadow mask is in close proximity to and matches the curvature of the processing drum. The position of the shadow mask to the processing drum is such that a uniform gap is created between the processing drum and shadow mask through which the OLED substrate passes during the deposition process. In certain embodiments, the width of the gap is from approximately 1 micron to approximately 2000 microns, preferably between 1 micron and 200 microns.

The shadow mask may be constructed of a low thermal expansion alloy such as Invar® and comprise one or more mask line features parallel to the moving direction of the drive rollers. The mask line features selectively prevent deposition of the coating on the OLED substrate to form lanes between coating bands; and one or more beam features perpendicular to the moving direction of the OLED substrate wherein the beam feature provide mechanical support to the line features.

Referring again to FIG. 7, the process further comprises providing a vapor deposition source, the vapor deposition source positioned to deposit a coating through the shadow mask to the OLED substrate, positioning the OLED substrate on the feed roll and take up roll such that the OLED substrate is wrapped around the processing drum and is in close approximation to the shadow mask, transporting the OLED substrate from the feed roll to the take-up roll using the drive roller, and depositing a coating on to the OLED substrate from the vapor deposition source.

In certain embodiments, the vapor deposition source may be selected from the group consisting of a thermal evaporation source, e-beam evaporation source, ion beam assisted evaporation source, plasma assisted evaporation source, DC sputtering, DC magnetron sputtering, AC sputtering, pulse DC sputtering, and RF sputtering.

In certain embodiments, the method may also comprise an alignment step to align the OLED substrate on the processing drum wherein the OLED substrate is positioned within a recess area on the processing drum during the coating process. In an alternative embodiment, the alignment step may involve the use of a guide control system monitors and adjusts the position of the OLED substrate on the processing drum.

In certain embodiments, the method may further comprising applying a second coating layer to the OLED substrate by providing a second processing drum and shadow mask wherein said second processing drum and shadow mask are positioned at a non-equal distances from the vapor deposition source compared to the first processing drum and shadow mask such that the first and second coating layer are applied to the OLED substrate at different deposition rates.

In other embodiments, the coating may also be applied with intervals to the OLED substrate by opening and closing a shutter device attached to the vapor deposition source.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An apparatus for applying a patterned coating to an OLED substrate in a roll-to-roll vapor based deposition process comprising:
a processing drum capable of positioning the OLED substrate for coating by a vapor deposition source;
a drive roller capable of transferring the OLED substrate from a feed roll to a take up roll and controlling tension of the OLED substrate on the processing drum; and
a shadow mask wherein the curvature of the shadow mask matches the curvature of the processing drum and wherein said shadow mask is positioned in close proximity to the processing drum to create a gap through which the OLED substrate is adapted to move from the feed roll to the take up roll without having physical contact with said shadow mask and wherein said shadow mask comprises;
one or more mask line features parallel to the moving direction of the OLED substrate wherein said mask line feature selectively prevents deposition of the coating on to one or more areas of the OLED substrate; and
one or more beam features perpendicular to the moving direction of the OLED substrate wherein said beam feature provides mechanical support to the line features.

2. The apparatus of claim 1 wherein the vapor deposition source is selected from the group consisting of a thermal evaporation source, e-beam evaporation source, ion beam assisted evaporation source, plasma assisted evaporation source, DC sputtering, DC magnetron sputtering, AC sputtering, pulse DC sputtering, and RF sputtering.

3. The apparatus of claim 1 wherein the shadow mask further comprises one or more support structures to attach the shadow mask to an axel of the processing drum.

4. The apparatus of claim 1 wherein the mask line features are comprised of curved metal bands wherein the curvature of the metal band matches the curvature of the processing drum and the thickness said metal band is determined by the width of the area on the OLED substrate that will form an uncoated pattern.

5. The apparatus of claim 1 wherein the one or more beam features are comprised of hollow metal tubing having a cooling channel to regulate temperature of the shadow mask.

6. The apparatus of claim 1 further comprising an alignment device to align the OLED substrate on the processing drum.

7. The apparatus of claim 6 wherein the alignment device comprises a recess area on the processing drum and wherein the OLED substrate is positioned within said recess area during the coating process.

8. The apparatus of claim 6 wherein the alignment device comprises a guide control system wherein said guide control system monitors and adjusts the position of the OLED substrate on the processing drum.

9. The apparatus of claim 1 wherein the distance between the processing drum and the shadow mask is from approximately 1 micron to approximately 2000 microns.

10. The apparatus of claim 1 wherein the shadow mask is comprised of a low thermal expansion alloy.

11. The apparatus of claim 10 wherein the low thermal expansion alloy is INVAR®.

12. The apparatus of claim 1 further comprising a second processing drum wherein a first processing drum and said second processing drum are positioned at non-equal distances from the vapor deposition source to allow two coating layers to be applied to the OLED substrate said coating layers being applied at different deposition rates.

13. The apparatus of claim 1 wherein the vapor deposition source further comprising a shutter device to intermediately prevent deposition of the coating onto the OLED substrate.

14. A method of applying a patterned coating to an OLED substrate in a roll-to-roll vapor based deposition process comprising:
providing an OLED substrate;
providing a drive roller to allow continuous movement of the OLED substrate from a feed roll to a take-up roll;
providing a processing drum and a shadow mask, positioned between the feed roll and the take-up roll, wherein the shadow mask is in close proximity to and matches the curvature of the processing drum and wherein the shadow mask comprises;
one or more mask line features parallel to the moving direction of the OLED substrate wherein said mask line feature selectively prevents deposition of the coating on to one or more areas of the OLED substrate; and
one or more beam features perpendicular to the moving direction of the OLED substrate wherein said beam feature provides mechanical support to the mask line features;
positioning the OLED substrate on the feed roll and take up roll such that the OLED substrate is wrapped around the processing drum and is in close approximation to the shadow mask;
transporting the OLED substrate from the feed roll to the take-up roll using the drive roller; and
depositing a coating on to the OLED substrate, through the shadow mask, from a vapor deposition source.

15. The method of claim 14 wherein the vapor deposition source is selected from the group consisting of a thermal evaporation source, e-beam evaporation source, ion beam assisted evaporation source, plasma assisted evaporation source, DC sputtering, DC magnetron sputtering, AC sputtering, pulse DC sputtering, and RF sputtering.

16. The method of claim 14 wherein the distance between the processing drum and the shadow mask is from approximately 1 micron to approximately 2000 microns.

17. The method of claim 14 wherein the shadow mask is comprised of a low thermal expansion alloy.

18. The method of claim 17 wherein the low thermal expansion alloy is INVAR®.

19. The method of claim 14 further comprising an alignment step to align the OLED substrate on the processing drum wherein said OLED substrate is positioned within a recess area on the processing drum during the coating process.

20. The method of claim 14 further comprising an alignment step to align the OLED substrate on the processing drum wherein a guide control system monitors and adjusts the position of said OLED substrate on the processing drum.

21. The method of claim 14 further comprising applying a second coating layer to the OLED substrate by providing a second processing drum and shadow mask wherein said second processing drum and shadow mask is positioned at a non-equal distances from the vapor deposition source compared to the first processing drum and shadow mask.

22. The method of claim 14 wherein the coating is applied intermediately to the OLED substrate by opening and closing a shutter device attached to the vapor deposition source.
